(19) United States
(12) Patent Application Publication
(10) Pub. No.: US 2005/0213744 A1
(43) Pub. Date: Sep. 29, 2005

(54) Retractable keyboard to be connected in a portable electronic device

(75) Inventor: Jari Valli, Tampere (FI)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: Nokia Corporation

(21) Appl. No.: 11/079,902

(22) Filed: Feb. 28, 2005

(30) Foreign Application Priority Data
Feb. 26, 2004 (FI) 20045058

(51) Int. Cl. H04M 1/00; H04M 3/00; G06F 1/16; H05K 5/00; H05K 7/00

(52) U.S. Cl. 379/368; 361/680

(57) ABSTRACT

The invention relates to a retractable keyboard of an electronic device having a closed position and an operating position. Said retractable keyboard (6, 6a, 6b, 26) is in the closed position arranged partly or completely inside (S) or underneath (U) said electronic device (1), and said retractable keyboard is directly ejectable to the operating position in parallel with the lengthwise axis of said electronic device.

### BACKGROUND OF THE INVENTION

The invention relates to a retractable keyboard that can be connected to a portable electronic device and electronic device provided with a retractable keyboard, as well as a method for manufacturing said retractable keyboard and electronic device.

In portable electronic devices, such as in mobile phones, there is generally used a basic keyboard where several different functions are integrated in one single key. One and the same basic key is used for writing, with different amounts of key strokes, for example the letters a, b and c as well as the number 2. This kind of keyboard is fairly cumbersome to use for example when writing text messages. An auxiliary keyboard could make the functions more versatile, but on the other hand, auxiliary keyboards increase the size of the device, and they may be difficult to use as such.

In the prior art there is known for instance the mobile phone Nokia 6800 provided with a retractable keyboard that can be turned open by hinges; the basic keyboard is arranged on the top surface of the retractable keyboard. By opening up the retractable keyboard, there is revealed an auxiliary keyboard. On the other side of the retractable keyboard, in the body of the mobile phone, there is yet another auxiliary keyboard that is set in the operating position when opening up the retractable keyboard. Hence the arrangement includes three different keyboards, and it is mechanically complicated and technically sensitive to damages.

### SUMMARY OF THE INVENTION

We have now invented a retractable keyboard and an electronic device connected thereto, both of which are made, with respect to their functions, very compact, so that they take up as little space as possible. In order to achieve this objective, the invention is characterized by the features set forth below.

According to an embodiment of the invention, the retractable keyboard is provided with one or several connecting elements for shiftably connecting the retractable keyboard inside a portable electronic device and/or underneath the device. Thus the retractable keyboard can in the closed position be stored inside or underneath the electronic device. From there, it can be directly ejected to the operating position outside the electronic device, as connected thereto.

Thus the retractable keyboard has both a closed position and an operating position, and in the closed position said retractable keyboard is arranged partly or completely inside or underneath said electronic device, and in the operating position, said retractable keyboard is directly shiftable in parallel with the lengthwise axis of said electronic device.

The retractable keyboard can be employed as an auxiliary keyboard and/or the basic keyboard of an electronic device.

According to an object of the invention, the electronic device is provided with a separate storage space for shiftably connecting the retractable keyboard thereto. In addition, the electronic device may include a fixed keyboard. Depending on the application in question, it may include a display, a function keypad, a microphone and/or a headphone/loudspeaker. The electronic device can be for example a mobile phone, a positioning device or a game arrangement, or a combination of these. The retractable keyboard according to the invention is also suited in other types of portable electronic devices, such as remote controls. The electronic device can be used for instance for sending, transmitting and/or receiving messages, such as SMS messages and MMS messages.

According to an object of the invention, in the retractable keyboard there is connected a shifting element for shifting the retractable keyboard from inside and/or underneath the electronic device and vice versa. According to an embodiment, the shifting element is spring-operated. In certain applications, there can also be used manually operated shifting elements.

According to an object of the invention, in the retractable keyboard there is connected an adjusting element for adjusting the operation of the shifting element. It can be for example a pressable button, by pressing which the retractable keyboard is shifted from the storage position to the operating position. In this embodiment, there is employed a spring-operated shifting element.

According to an object of the invention, in the retractable keyboard there is connected a fastening element for fastening the retractable keyboard to the cover of the electronic device for operating the keyboard. Also the cover of the electronic device can be provided with a fastening element. The fastening element is connected to the adjusting element of the shifting element, for example to a pressable button. In that case the pressable button is provided for instance with a pin that locks the retractable keyboard in the storage position and/or in the operating position.

According to an object of the invention, to the retractable keyboard there is connected a converting element for converting the display position of the keys of the retractable keyboard for instance by 90°. The employed converting element is the shifting element and/or the adjusting element of the shifting element. The converting element can be an illumination-operated converting element or a mechanical converting element.

According to an object of the invention, the electronic device includes a display and said device and/or retractable keyboard includes a turning element for turning the display position of the display of the electronic device for example by 90°. In order to synchronize the turning of the display position of the display and the shifting of the retractable keyboard so as to take place simultaneously, the turning element is functionally connected to the shifting element and/or to the adjusting element, or the turning element constitutes a functional part of the shifting element and/or adjusting element. For example mobile phones are provided with a pressable button operated adjusting element of the shifting element, where by pressing the button, the retractable keyboard is released from inside the mobile phone, and simultaneously the display position of the display is turned, and the position of a possible fixed keyboard is changed.

According to an object of the invention, the retractable keyboard is SW(software)-configurable. Also the fixed keyboard can be SW-configurable. This gives special advantage to many embodiments of the invention.

The fixed keyboard comprises a storage space, a fastening element, a shifting element, an adjusting element, a turning element and/or a converting element. This is advantageous for example when aiming at manufacturing an electronic device provided with a retractable keyboard that fits in an especially small space.

The device according to the invention can be for instance a mobile phone provided with a fixed keyboard and a retractable keyboard that can be shifted inside the fixed keyboard. The device includes a button, by pressing which the retractable keyboard can be ejected. At the same time the display position of the display is turned from the vertical to the horizontal direction by 90 degrees, and also the display position of the fixed keyboard is respectively changed by 90 degrees. The fixed keyboard can include additional pressable or push buttons that are not in use in the vertical position. By means of the keypad of the retractable keyboard and the keypad of the fixed keyboard, for instance text messages can be written effortlessly, in comparison with the cumbersome use of one single fixed keyboard.

Other functions can also be connected to an electronic device, for example to a mobile phone. By means of the retractable keyboard, it is for instance possible to control the photography operations of a camera phone and/or the transmitting of images.

### BRIEF DESCRIPTION OF THE DRAWINGS

Some embodiments of the invention are described in more detail below, with reference to the appended drawings.

FIG. 1 illustrates a retractable keyboard that is retractably installed inside a mobile phone provided with a fixed keyboard, according to the present invention.

FIG. 2 illustrates a retractable keyboard according to FIG. 1, as ejected from inside the mobile phone to the operating position.

FIG. 3 illustrates a mobile phone with two retractable keyboards ejected from inside the mobile phone, according to the present invention.

FIG. 4 illustrates a retractable keyboard ejected from underneath a mobile phone provided with a fixed keyboard, according to the present invention.

FIG. 5 is a top-view illustration of the mobile phone of FIG. 1.

FIG. 6 is a top-view illustration of the mobile phone of FIG. 2.

FIG. 7 is a top-view illustration of another mobile phone, according to the present invention.

FIG. 8 is a top-view illustration of a mobile phone provided with two retractable keyboards, where the two retractable keyboards are invisible in the storage position, according to the present invention.

FIG. 9 illustrates the mobile phone of FIG. 8, where one of the retractable keyboards is ejected to the operating position.

FIG. 10 is a top-view illustration of the mobile phone of FIG. 8, where the two retractable keyboards are ejected to the operating position.

### DETAILED DESCRIPTION OF THE INVENTION

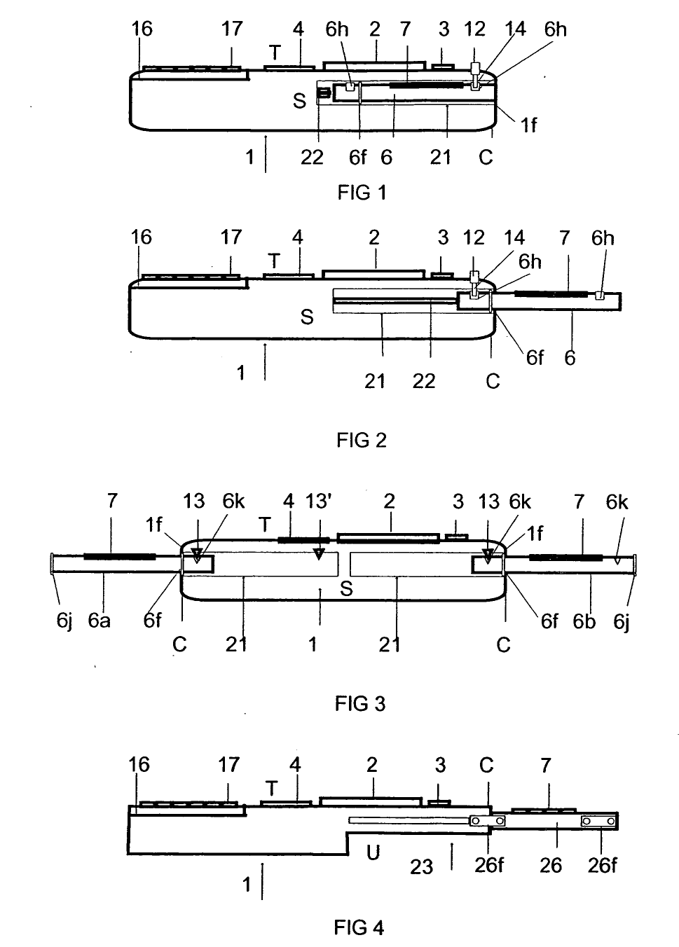

In FIGS. 1 and 2, a retractable keyboard 6 provided with keys 7 is connected to a mobile phone 1. On top T of the mobile phone 1, there is arranged a fixed keyboard 16 provided with a keypad 17 and a display 2, as well as a loudspeaker 3 and a function keypad 4. To the retractable keyboard 6, there is connected a connecting element 6h for connecting the retractable keyboard 6 to a storage space 21. The arrangement includes a spring-operated shifting element 22 for shifting the retractable keyboard 6 in various positions. The arrangement also includes an adjusting element 12, by which the position of the retractable keyboard 6 can be adjusted. In FIG. 1, the retractable keyboard 6 is adjusted to remain inside S the mobile phone 1, and in FIG. 2 it is ejected, by means of the adjusting element 12 and the spring-operated shifting element 22 essentially to outside the cover C of the mobile phone 1, to the operating position. The retractable keyboard is provided with a fastening element 6f, and the cover C is provided with a fastening element 1f for fastening the retractable keyboard 6 for example to the cover C of the mobile phone 1. In addition, the cover C is provided with claw fasteners 1f for fastening the retractable keyboard 6 to the cover C.

In FIG. 3, two retractable keyboards 6a, 6b provided with keys 7 are connected to a mobile phone 1. On top T of the mobile phone, there is arranged a display 2, a loudspeaker 3 and a function keypad 4. To the retractable keyboards 6a, 6b, there are connected connecting elements 6k for connecting the retractable keyboards 6 to the storage spaces 21 provided inside S the mobile phone 1. The arrangement includes manual shifting elements 6j for shifting the retractable keyboards 6a, 6b in various positions. The arrangement also includes connecting elements 13, 13′, by which the position of the retractable keyboards 6a, 6b can be adjusted. The retractable keyboards 6a, 6b are shifted, by means of the adjusting element 12 and the manual shifting elements 6j for example to outside the cover C of the mobile phone 1, to the operating position. The retractable keyboards are provided with fastening elements 6f for fastening the retractable keyboard 6 for instance to the cover C of the mobile phone 1. The cover C also includes claw fasteners 1f for fastening the retractable keyboard 6 to the cover C.

In FIG. 4, a retractable keyboard 26 provided with keys 7 is connected to a mobile phone 1. On top T of the mobile phone, there is a fixed keyboard 16 provided with a keypad 17 and a display 2, a loudspeaker 3 and a function keypad 4. To the retractable keyboard 26, there is connected a connecting element 26f for connecting the retractable keyboard 26 to the storage space 23 underneath U the mobile phone 1. The retractable keyboard 26 can be manually shifted to various positions. The retractable keyboard 26 is for instance ejected to outside the cover C of the mobile phone 1, to the operating position. The connecting element 26f simultaneously fastens the retractable keyboard 26 for instance to the cover C of the mobile phone 1.

FIG. 5 is a top-view illustration of a mobile phone according to FIG. 1. Both the display position 9v of the display and the display position 17v of the keys are normally vertical when used, i.e., oriented 90° counter-clockwise from that shown so that the typeface is displayed for vertical viewing on the keys to a user.

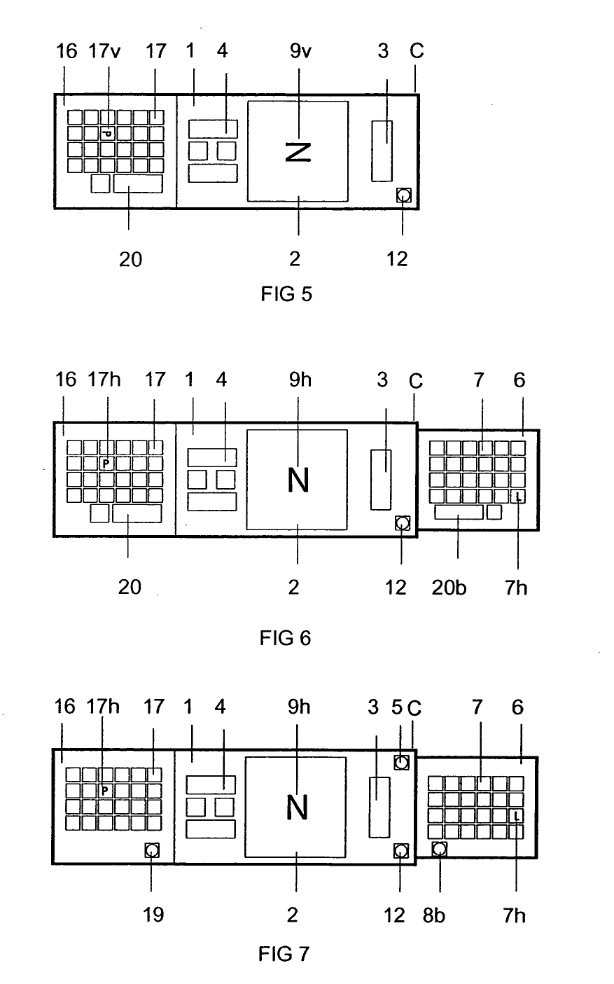

FIG. 6 is a top-view illustration of a mobile phone according to FIG. 2. The display position 9h of the display and the display position 17h of the keys are in this case both normally horizontal when in use, i.e., oriented as shown in FIG. 6. These have changed when the adjusting element 12 has been pressed for ejecting the retractable keyboard 6 to the operating position. In addition, in the fixed keyboard 16 there can be seen function keys 20, and in the retractable keyboard there can be seen function keys 20b. The retractable keyboard may be SW-configurable.

FIG. 7 is a top-view illustration of another alternative mobile phone 1 according to FIG. 2. The display position 9h of the display and the display position 17h of the keys are both horizontal, as in FIG. 6. These have changed from that shown in FIG. 5, when the adjusting element 12 has been pressed for ejecting the retractable keyboard 6 to the operating position. In addition, the fixed keyboard 16 includes a converting element 19 for adjusting the display position 17h of the keyboard, and the retractable keyboard includes a converting element 8b for converting the display position 7h of the keyboard. These 8b, 19 can serve as alternative converting elements for the adjusting element 12. Moreover, the mobile phone includes an alternative display turning element 5 for turning the display position 9h of the display 2.

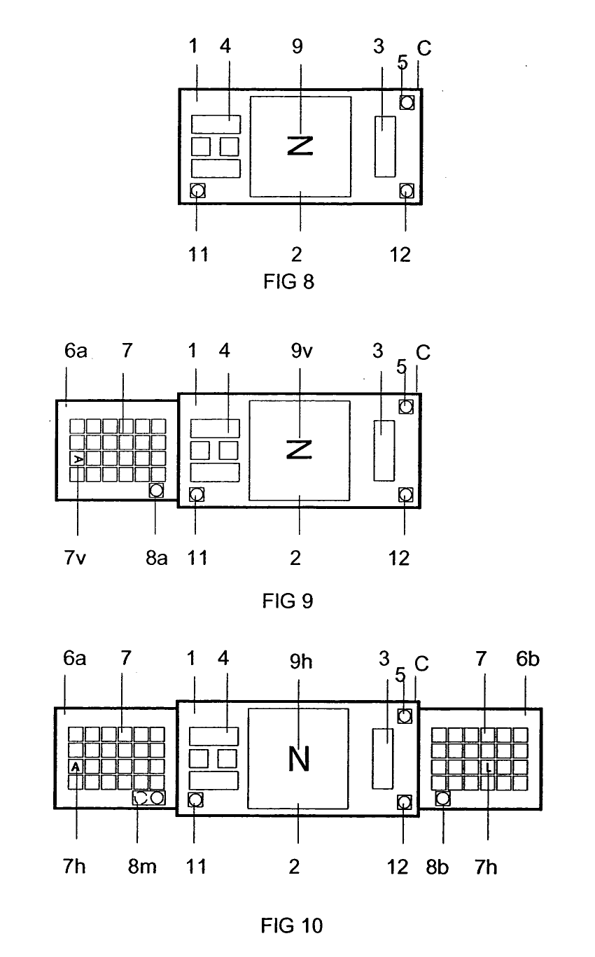

FIGS. 8, 9 and 10 illustrate a mobile phone 1 provided with two retractable keyboards. On top of the mobile phone, there is a display 2, a loudspeaker 3 and a function keypad 4. The arrangement also includes adjusting elements 11, 12, for adjusting the position of the retractable keyboards 6a, 6b and preferably for simultaneously converting the display position 9h, 9v of the display and/or the display position 7h, 7v of the keys. Moreover, the mobile phones 1 include an alternative display turning element 5 for turning the display position 9h, 9v of the display 2, and the retractable keyboards include a converting element 8b, 8m for alternatively converting the display positions 7h of the keyboards. The converting element 8m of one retractable keyboard 6a is manually operated, and the converting element 8b of the other retractable keyboard 6b is illumination-operated.

1. Portable electronic device having a retractable keyboard having a closed position and an operating position and a display wherein said retractable keyboard in the closed position is arranged partly or completely inside or underneath said electronic device, and to the retractable keyboard is connected an adjusting element used to eject said retractable keyboard by means of a shifting element to the operating position in parallel with a lengthwise axis of said electronic device and wherein the electronic device includes, or the retractable keyboard includes, or both include a turning element for turning a display position of the display by a selected angle, and in order to synchronize turning of the display position of the display and a shifting of the retractable keyboard so as to take place simultaneously, the turning element is functionally connected to the shifting element, or to the adjusting element, or both, or the turning element forms a functional part of the shifting element, or of the adjusting element, or both.

2. The portable electronic device according to claim 1, where to the retractable keyboard there is connected the shifting element for shifting the retractable keyboard from inside the electronic device, or from underneath it, or both, and for shifting the retractable keyboard from outside the device to inside.

3. The portable electronic device according to claim 2, wherein said shifting element is a spring-operated shifting element.

4. The portable electronic device according to claim 1, wherein said shifting element is a manually operated shifting element.

5. The portable electronic device according to claim 1, wherein said adjusting element is for adjusting operation of the shifting element.

6. The portable electronic device according to claim 1, where to the retractable keyboard there is connected a fastening element for fastening the retractable keyboard to a cover of the electronic device in order to use said electronic device.

7. A portable electronic device according to claim 1, wherein to the retractable keyboard there is connected a converting element for converting a display position of keys of the retractable keyboard by 90°.

8. A portable electronic device according to claim 7, where the converting element is an illumination-operated converting element.

9. A portable electronic device according to claim 7, where the converting element is a mechanical converting element.

10. A portable electronic device according to claim 1, where said electronic device is provided with a storage space for retractably connecting the retractable keyboard.

11. A portable electronic device according to claim 1, where said device also includes a fixed keyboard.

12. A portable electronic device according to claim 1, where the retractable keyboard is software-configurable.

13. A portable electronic device according to claim 11, where to the fixed keyboard, there is connected a storage space, a fastening element, a shifting element, an adjusting element, and a turning element, or a converting element, or both.

14. A portable electronic device according to claim 1, where the portable electronic device is a mobile phone.

15. Method for manufacturing a portable electronic device having a retractable keyboard and having a closed position and an operating position and a display, where said retractable keyboard is in the closed position partly or completely inside or underneath said electronic device, and wherein said retractable keyboard can be directly ejected by a shifting element to the operating position in parallel with a lengthwise axis of said electronic device and to the retractable keyboard is connected an adjusting element and the adjusting element inlcudes, or the retractable keyboard includes, or both include, a turning element for turning a display position of the display by a selected angle, and in order to synchronize turning of the display position of the display and a shifting of the retractable keyboard so as to take place simultaneously, the turning element is functionally connected to the shifting element, or to the adjusting element, or both, or the turning element forms a functional part of the shifting element, or of the adjusting element, or both.

16. The method according to claim 15, wherein said shifting element is for shifting the retractable keyboard from inside of the electronic device to outside, or from outside it to inside, or both.

17. The method according to claim 16, where the shifting element is a spring-operated shifting element.

18. The method according to claim 16, where the shifting element is a manually operated shifting element.

19. The method according to claim 15, where to the retractable keyboard there is connected an adjusting element for adjusting the operation of the shifting element.

20. The method according to claim 15, where to the retractable keyboard there is connected a fastening element for fastening the retractable keyboard to a cover of the electronic device in order to use the device.

21. The method according to claim 15, where to the retractable keyboard there is connected a converting element for converting a writing position of the retractable keyboard by 90°.

22. The method according to claim 15, where the device is provided with a storage space for retractably connecting the retractable keyboard.

23. The method according to claim 15, where to the device there is connected a fixed keyboard.

24. The method according to claim 15, where to the device there is connected a display, and that to the retractable keyboard, or to the device, or both, there is connected a turning element for turning the display position of the display of the device.

25. The method according to claim 15 for manufacturing a portable electronic device, where the portable device is a mobile phone.

26. The use of an electronic device, conforming to claim 1, where said device is used for sending, or receiving messages, or both.

27. The use according to claim 26, where the retractable keyboard is used as an auxiliary keyboard of the electronic device.

28. The use according to claim 26, where the retractable keyboard is used as a basic keyboard of the electronic device.

29. The use according to claim 26, where the electronic device is a mobile phone.
